(19) United States
(12) Patent Application Publication
(10) Pub. No.: US 2017/0361405 A1
(43) Pub. Date: Dec. 21, 2017

(54) IRRADIATION SYSTEM FOR AN ADDITIVE MANUFACTURING DEVICE

(71) Applicant: TRUMPF Laser- und Systemtechnik GmbH, Ditzingen (DE)

(72) Inventors: Bernd Hermann Renz, Marbach (DE); Frank Peter Wüst, Herrenberg (DE); Johannes Bauer, Illingen (DE)

(21) Appl. No.: 15/690,378

(22) Filed: Aug. 30, 2017

Related U.S. Application Data
(63) Continuation of application No. PCT/EP2016/054269, filed on Mar. 1, 2016.

(30) Foreign Application Priority Data
Mar. 4, 2015 (DE) 102015103127.2

(51) Int. Cl. B23K 26/342; B33Y 30/00; H01S 5/022; H01S 5/00; H01S 3/0941; B33Y 50/02; H01S 3/00; B28B 1/00; B23K 26/06; B23K 26/70; B23K 26/082; B23K 26/0622; H01S 5/40; H01S 3/06

(52) U.S. Cl. CPC B23K 26/342; H01S 5/4025; B33Y 30/00; H01S 5/02284; H01S 5/0071; H01S 3/0941; H01S 3/06; H01S 3/0071; B28B 1/001; B23K 26/0626; B23K 26/0608; B23K 26/705; B23K 26/082; B23K 26/0622; B33Y 50/02; H01S 5/4012

(57) ABSTRACT

An irradiation system includes: a first beam source configured to output a first laser beam and a second beam source configured to output a second laser beam, in which the second laser beam has a higher beam quality higher than that of the first laser beam;

optics arranged to focus the first and second laser beams; and a beam guiding system including a first beam path along which the first laser beam is guided, and a second beam path along which the second laser beam is guided, in which the beam guiding system includes a beam combiner to superimpose the first and second laser beams, the first beam source is a pump laser, the second beam source is a laser resonator, and the beam guiding system further includes a beam switch adapted to feed the first laser beam into a pump laser beam path and/or into the first beam path.

### CROSS-REFERENCE TO RELATED APPLICATIONS

This application is a continuation of and claims priority under 35 U.S.C. §120 from PCT Application No. PCT/EP2016/054269 filed on Mar. 1, 2016, which claims priority from German Application No. 10 2015 103 127.2, filed on Mar. 4, 2015. The entire contents of each of these priority applications are incorporated herein by reference.

### TECHNICAL FIELD

The present disclosure relates to an irradiation system for a device for laser-based additive manufacturing.

### BACKGROUND

Laser-based additive manufacturing of, particularly metal or ceramic, workpieces is based on consolidation/solidification of a, e.g. powder, basic material by irradiation with laser light. This concept—also known as selective laser melting (SLM) or powder bed fusion—is, among other things, used in machines for 3D printing, e.g., 3D printing of metal. An exemplary machine for manufacturing three-dimensional products is disclosed in European patent application EP 2 732 890 A2 by Sisma S.p.A. Advantages of additive manufacturing include, e.g., easy manufacturing of complex and individually producible components. In particular, defined interior structures and/or force-flow optimized structures can be realized using additive manufacturing.

In laser-based additive manufacturing, a workpiece is segmented into a skin (also referred to as “skin areas”) and a core (also referred to as “core areas”), sometimes referred to as a skin-core strategy. Thereby, skin and core can be irradiated with correspondingly adapted beam shapes.

### SUMMARY

The present disclosure relates to an irradiation system for an additive manufacturing device. Among other things, the present disclosure relates to providing multiple laser beam configurations for additive manufacturing, and methods for adjusting a spatially adapted irradiation for an additive manufacturing process of a workpiece in a laser-based additive manufacturing device.

In general, in one aspect, the subject matter of the present disclosure covers an optical irradiation system for an additive manufacturing device, which allows for an irradiation with different beam profiles in additive manufacturing. In general, in another aspect, the subject matter of this disclosure covers methods for increasing the build-up rate and process efficiency of laser-based generative methods, such as in the context of the skin-core strategy.

In general, in an aspect, the subject matter of the present disclosure covers an irradiation system for a device for laser-based additive manufacturing, in which the system includes a first beam source of a first laser beam and a second beam source of a second laser beam, the second laser beam having a beam quality higher than that of the first laser beam. The irradiation system further includes a common scanner optics for focusing the first laser beam and the second laser beam within a manufacturing space, and a beam guiding system having a first beam path for guiding the first laser beam from the first beam source to the scanner optics, and a second beam path for guiding the second laser beam from the second beam source to the scanner optics. The beam guiding system additionally includes a beam combiner for superimposing the first and second beam paths.

In general, in another aspect, the subject matter of the present disclosure covers methods for adjusting a spatially adapted irradiation for additive manufacturing of a workpiece in a laser-based additive manufacturing device, in which the device includes a scanner optics and a powder bed having metal powder. The methods can include providing a first laser beam and a second laser beam, in which the second laser beam for fine irradiation of the powder bed has a beam quality higher than that of the first laser beam. Further, the first laser beam and the second laser beam are superimposed into a beam path, and the energy inputs of the first laser beam and the second laser beam are adjusted in the scanner unit. The first laser beam and the second laser beam are scanned over the powder bed for alternating or simultaneous irradiation of the powder bed with the first laser beam and the second laser beam.

In some embodiments of an additive manufacturing device, a laser system including one or more pump lasers (e.g. diode lasers) and an associated laser resonator are provided with at least one beam switch, so that the at least one pump laser can be either used for pumping a laser medium of the laser resonator (which is, for example, formed as a disk or a fiber), or can be decoupled for direct irradiation of the powder bed. Generally, a pump laser beam is generated more energy-efficiently than a laser beam from the laser resonator. However, as a pump laser beam usually has a worse beam profile than the beam from the laser resonator, a pump laser beam cannot be focused to a diameter, which is as small as that of the laser beam exiting the laser resonator. Thus, pump laser beams are usually not suitable for irradiating the powder bed in the skin area. However, a pump laser beam may be used for energy-efficient irradiation of the core area instead.

In some embodiments, the pump laser beam is coupled into a transport fiber immediately after being coupled out of the beam path to the laser medium/laser resonator, and guided to an optics of the additive manufacturing device (e.g. an SLS/SLM machine) via the transport fiber. The optics may, for example, include a beam combiner and a scanner optics. Due to the comparatively low beam quality of the pump laser beam, the transport fiber may have a relatively large diameter in order to be able to completely couple the pump laser beam into the transport fiber. However, the pump laser beam subsequently exiting the fiber may not be focused small enough for the skin area, such that the (energy-efficient) beam exiting the transport fiber is only suitable for processing the core area. The laser beam of the laser resonator can also be coupled into a transport fiber; due to its better beam quality, however, it can be coupled into a fiber having a small diameter. The transport fiber guides the laser beam having a high beam quality to the optics of the additive manufacturing device. The radiation exiting the small-diameter fiber can be focused to a small diameter and is therefore suitable for processing the skin area.

In some embodiments, a split laser beam or two different laser beams may be coupled into a single transport fiber. For example, a pump laser beam may be coupled into an annular fiber jacket and a laser beam exiting the laser resonator and having a better beam profile may be fed into the fiber core of the transport fiber. Via the transport fiber, the laser light, which includes components of the pump laser beam and the resonator laser beam, is guided to the optics of the additive manufacturing device, and moved with a scanner optics over a powder layer area to be melted. The radiation exiting the annular fiber jacket has a larger focus diameter than the beam exiting the fiber core and can heat the powder over a larger radius around the focus point of the beam exiting the fiber core. This heating within the radiated space may be close to the melting temperature. Further, the scanning speed and/or the portion of the pump laser beam coupled into the fiber jacket may be adjusted to a corresponding energy input. Generally, the relation of laser beam outputs exiting the fiber core and the fiber jacket may be adapted to each other such that the powder in the surrounding area of the processing point is reliably heated by the laser beam exiting the fiber jacket, up to an range below the melting temperature, and, consequently, the laser beam exiting the fiber core needs to contribute only little energy in order to melt the powder. In this manner, irradiation may be performed by a single quick movement of the laser beam consisting of the two beam components over the processing region.

In some embodiments, a powder temperature of the powder bed, in particular in the moving direction of the laser beams, is, for example, detected by an IR camera, and the performance of the two laser beams and/or the scanning speed is/are controlled to a suitable energy input.

In some embodiments, it may be additionally possible to block the laser beam exiting the fiber core, such that only laser radiation through the fiber jacket is guided to the powder bed to input energy. This approach may be applied, e.g., for melting the core in the context of a skin-core strategy.

Some embodiments of the systems, devices and method described herein may allow for faster manufacturing of workpieces like, for example, SLM components, as well as for a more favorable production due to an increased utilization efficiency of the beam sources. Further, in some embodiments, advantages of the different types of beam sources can be better exploited, e.g., fiber/disk lasers for high detail resolution, and direct diode lasers for fast irradiation of large areas.

The concepts described herein particularly relate to the manufacturing of components where the above described subdivision into different areas of geometry, e.g., into a skin (skin areas) and a core (core areas), is performed.

Herein, concepts are disclosed that allow to at least partly improve aspects of the prior art. In particular additional features and their functionalisms result from the following description of embodiments on the basis of the drawings. The drawings show:

### DESCRIPTION OF DRAWINGS

FIG. 1 is a schematic illustrating an exemplary additive manufacturing device including an irradiation system.

FIG. 2 is a schematic illustrating an exemplary additive manufacturing device including an irradiation system.

FIG. 3 is an exemplary flow diagram illustrating a method for adjusting spatially adapted irradiation for additive manufacturing of a workpiece in a laser-based additive manufacturing device.

### DETAILED DESCRIPTION

In laser-based additive manufacturing, the structure in the moment of melting is generally determined by the spatial extent and the development of the energy input by the laser beam. A corresponding spatial determination of the energy input allows for generation of three-dimensional, highly complex components, which may, for example, have undercuts and numerous internal structures.

The subject matter described herein is partly based on the realization that selective or simultaneous (and potentially weighted) coupling of laser beams having different beam qualities into a common beam path of a scanning unit may allow setting specially defined energy inputs. Thereby, different areas of geometry of a workpiece can be exposed to irradiation with correspondingly adapted process efficiency. Herein, beam quality may be understood to include the quality of a laser beam with regard to its focusability.

Moreover, the use of a diode-laser pumped resonator in an irradiation system of a device for additive manufacturing allows using the laser beam generated in the resonator, which has a high beam quality, and, in addition, the pump beam of the diode laser for the additive manufacturing. Thus, two laser beams having different beam qualities are available (alternatingly or simultaneously) for the manufacturing process, in which the beam having the lower beam quality is efficiently generated by the diode laser. On the one hand, this concept allows for providing sufficient energy input for large volumes. In skin-core strategies, in particular, it may be used for generating the core quickly and efficiently. On the other hand, this concept allows using the beam having the lower beam quality for preparing the melting by the beam having the high beam quality and/or for influencing the cooling behavior after the melting.

Further, beams having different beam qualities can be flexibly guided to a (common) scanner optics by a transport fiber.

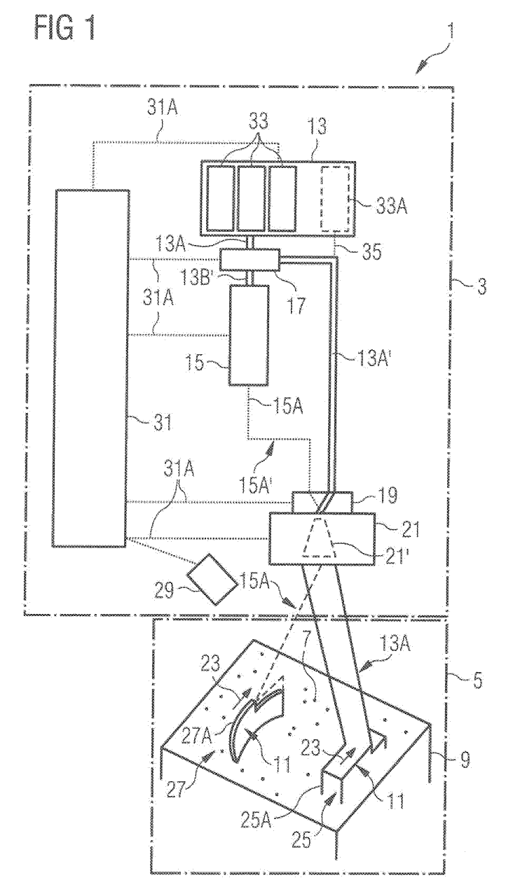

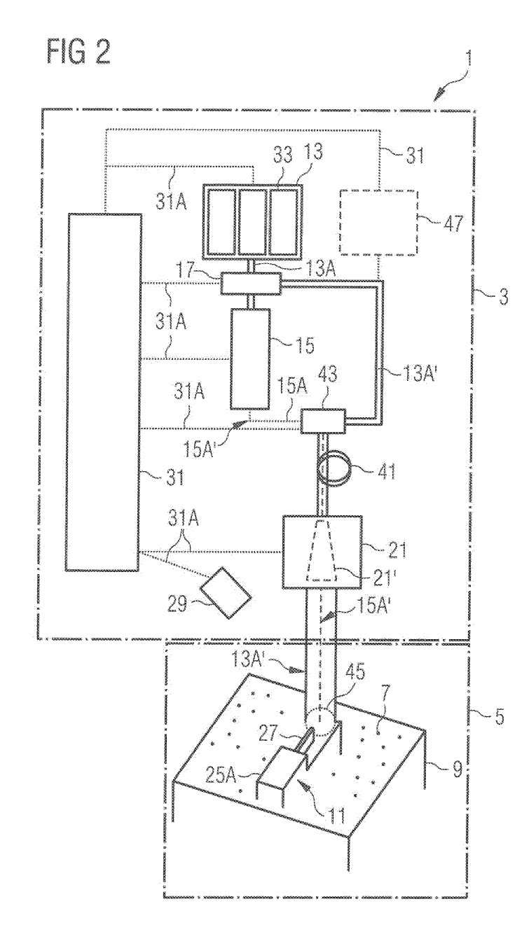

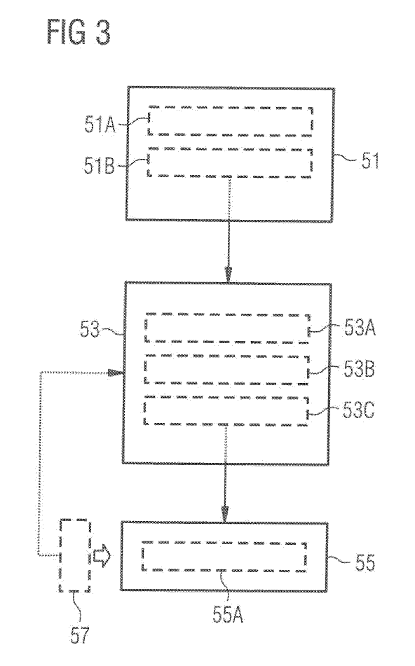

In the following, exemplary embodiments of irradiation systems for providing two laser beams having different beam qualities for additive manufacturing devices will be explained with reference to FIGS. 1 and 2. In FIG. 1, an alternating irradiation is exemplarily indicated, and in FIG. 2, a simultaneous irradiation with the laser beams is exemplarily indicated. Thereafter, exemplary processes of additive manufacturing are described with reference to FIG. 3.

An additive manufacturing device 1 includes an irradiation system 3 and a production space 5. Usually, the production space 5 is located in a chamber flooded with inert gas. Production space 5 comprises a powder bed 9 filled with, e.g. metal or ceramic, powder 7. The irradiation system 3 is adapted for generating laser light, which melts the powder 7 into material layers of a work-piece 11.

To generate the laser light, the irradiation system 3 includes a first beam source 13 and a second beam source 15. In the embodiment according to FIG. 1, the first beam source 13 is a pump laser (e.g., a diode laser). The second beam source 15 is a laser resonator (e.g., a fiber laser or a disk laser), the laser medium of which is pumped by the first beam source 13.

The first beam source 13 generates a first laser beam 13A, to which a first beam path 13A′ is assigned. The second beam source 15 generates a second laser beam 15A, to which a second beam path 15A′ is assigned. The first beam path 13A′ and the second beam path 15A′ are pro-vided by a beam guiding system, which, for example, comprises at least one transport fiber, mirrors, and lenses (not illustrated) for forming the beam paths.

For pumping the laser medium of the second beam source 15, the first laser beam 13A, or a portion thereof, is coupled into the laser resonator, such that the second laser beam 15A can be correspondingly coupled out of the laser resonator.

Examples of pump laser parameters are wavelengths in the range of, for example 900 nm to 1000 nm for pump diode lasers having a beam quality of, for example, 8 and a beam parameter product in the range of, for example, 30 mm mrad to 50 mm mrad.

Examples for parameters of the laser resonator are wavelengths in the range of, for example, 1030 nm for fiber lasers and wavelengths in the range of, for example, 1064 nm for disk lasers at beam parameter products in the range of, for example, 4 mm mrad to 25 mm mrad. Further, the lasers may be configured as CW lasers or pulsed lasers for certain areas of geometry, in particular hang over regions or regions of increased surface quality. Generally, the beam quality of the second laser beam 15A (resonator laser beam) is higher than that of the first laser beam (pump laser beam). Accordingly, the former can be focused to a smaller focus area. In the Figures, the first laser beam is illustrated by a double line, and the second laser beam is illustrated by a slender dashed line for clarification.

Further, the irradiation system 3 includes a beam switch 17 as part of the beam guiding system. Beam switch 17 is arranged in the beam path between the first beam source 13 and the second beam source 15, and allows for feeding the entire first laser beam 13A, or a portion thereof, into the laser resonator (along pump beam path 13B′) or into the first beam path 13A′. In the following, the first laser beam 13A is regarded as that portion of the radiation of the first beam source 13, which propagates along the first beam path 13A′, in which, at simultaneous irradiation by the first and second laser beams, a certain pump proportion of the radiation from the first beam source 13 is fed into the second beam source 15.

The configuration of the beam guiding system allows using at least part of the radiation from the first beam source 13 (e.g., the first laser beam 13A) separately from the pump proportion, for additive manufacturing. The beam switch 17 can, for example, enable discrete switching between the first beam path 13A′ and the pump beam path 13B′. Alternatively or additionally, a gradual or stepwise distribution of the radiation from the first beam source 13 to the first beam path 13A′ and the pump beam path 13B′—as an example for an adjustable beam switch 17—may be produced. Examples for beam switches include various types of partially transparent mirrors having different transmission/reflection ratios, which may be set in the beam path, as well as rotatable, partially transparently coated disks having split ratios, which gradually vary at their circumferences, or optical modulators like, for example, Bragg or Pockels cells.

The irradiation system 3 further includes a beam combiner 19 and a scanner optics 21. The beam combiner 19 superimposes the first beam path 13A′ of the first laser beam 13A and the second beam path 15A′ of the second laser beam 15A. The superposition is, for example, performed on a superpositioned beam path 21′ of the scanner optics 21. Examples of beam combiners include dichroitic mirrors, which transmit the wavelength of one laser and reflect the wavelength of the other laser, as well as diffraction gratings.

Accordingly, the scanner optics 21 can guide the first laser beam 13A and/or the second laser beam 15A over the powder 7 in the powder bed 9 along a settable scanning path 23.

In FIG. 1, for explaining the beam switch 17, which is, for example, formed as a discrete beam switch, a deflection of the first laser beam 13A is directed to a (core) section 25 of the work-piece 11. Section 25 corresponds to an area of geometry of the workpiece 11, which is, for example, associated with the core (e.g. a core area 25A) in a skin-core strategy. FIG. 1 further shows a deflection of the second laser beam 15A to a (skin) section 27 of workpiece 11. In a skin-core strategy, for example, section 27 corresponds to an area of geometry associated with the skin (e.g. skin area 27A). In a discrete beam switch, melting of the core area 25A and the skin area 27A is carried out section by section sequentially.

Irradiation system 3 further includes a monitoring device 29, e.g., an infrared camera. Monitoring device 29 detects information on the interaction region of the laser beams with the powder 7. Monitoring device 29, for example, captures a spatial and/or chronological temperature profile, or a temperature value in the focus area of the scanner optics 21, e.g., in the focus of the laser beams on the powder bed.

Irradiation system 3 further includes a control device 31. Control device 31 is adapted for controlling the irradiation process, such as adjusting the irradiation and for adjusting the associated energy inputs of the first laser beam 13A and the second laser beam 15A. Control device 31 is, for example, connected with the first beam source 13, the second beam source 15, the beam switch 17, the beam combiner 19, the scanner optics 21, and/or the monitoring device 29 via control connections 31A.

Via the control connections 31A, control device 31 can receive operating parameters and/or measuring information, correspondingly process the same, and, based thereon, issue control commands to corresponding components via the control connections 31A. Generally, allocation of the respective laser beam to be used is performed by a process as, for example, described in connection with FIG. 3, which process may be provided by a process software for manufacturing of components.

In an embodiment as exemplarily illustrated in FIG. 1, the first beam source 13 may include multiple diode laser units 33. Accordingly, the beam switch 17 may act on a combined laser beam, comprising inputs of all diode laser units 33. Alternatively or additionally, the beam switch 17 can act on an individual beam portion of an individual diode laser unit, or on a sub-group of diode laser units. In the latter case, for example, a number of diode laser units 33 can be provided as a first subgroup of diode laser units 33, and used for pumping the laser medium of the second beam source 15. A second subgroup of diode laser units 33A can be primarily used for generating the first laser beam 13A. Accordingly, diode laser units may be only provided for feeding laser light into the first beam path 13A′ (in FIG. 1, for example, diode laser unit 33A via beam path 33A′).

In some embodiments, the corresponding output of the first beam source 13 can be, e.g., continuously or gradually adjustable, modified by controlling the individual current of the diode laser units 33.

FIG. 2 illustrates further embodiments of the additive manufacturing device 1, in which the reference numerals of FIG. 1 are maintained where possible, in order to simplify the illustration. Components denoted by the same reference numeral are regarded as substantially similar components. In detail, however, they may differ due to their (slightly) different functionalities.

A difference of the embodiment according to FIG. 2 lies in the use of a common transport fiber 41 in the beam guiding system for the first laser beam 13A and the second laser beam 15A. The transport fiber 41 may provide part of a virtually common beam path. Accordingly, the beam guiding system includes a beam combiner 43, which allows for coupling the different beams into the transport fiber 41. For example, the first laser beam 13A and the second laser beam 15A, e.g., the first beam path 13A′ and the second beam path 15A′, are firstly superimposed on each other and then commonly coupled into the transport fiber 41 by a focusing optics (not shown). Alternatively, they can be coupled into the transport fiber 41 separately.

In some embodiments, the transport fiber 41 can have a first transport area having small extent, e.g., in the area of the fiber core, for the transport of the second laser beam 15A. Due to the fact that it is generated in a laser resonator, the second laser beam 15A has a high beam quality and can be focused correspondingly small in comparison to the pump laser beam, thus allowing for focusing and coupling into a small fiber core area of the transport fiber 41. Thus, after exiting the transport fiber 41, the second laser beam 15A diverges strongly, but maintains its high beam quality, such that focusing to a small focus area having a diameter of preferably less than 200 in particular some 10 μm, may be caused by the scanner optics 21. This focusing area is, for example, in the center of an interaction zone 45 indicated in FIG. 2, which has a diameter in the range of 100 μm to 5 mm, or is at least larger than the diameter of the focus area, in particular 0.3 mm to 1 mm.

The first laser beam 13A of the first beam source 13 has a lower beam quality, such that it can be coupled into a larger spatial area of the transport fiber 41, e.g., into a ring core or fiber jacket surrounding the fiber core. Accordingly, the divergence of the beam exiting the fiber is smaller, and the focal size of the first laser beam 13A is correspondingly larger in the interaction zone 45.

Depending on the method of coupling, the transport fiber 41 can separate the areas for the first laser beam 13A and the second laser beam 15A by intermediate cladding structures, or can merge the areas. Exemplary transport fibers are disclosed in

German patent application DE 10 2010 003 750 A1. The use of transport fibers without intermediate cladding can facilitate coupling of the first laser beam.

As an alternative to a fiber core and ring core, fiber bundle structures can be used. An example of a fiber coupler is described in DE 10 2012 209 628 A1 and could be used as a beam combiner 43, in which at least one fiber core of the fiber bundle structures has a small diameter, in order to transport the coupled-in second laser beam 15A without substantially reducing its high beam quality.

Several additional fibers of the fiber bundle structures have a larger extent and are, thus, suitable for coupling in the first laser beam 13A′. These additional fibers may be arranged, in particular annularly, around the at least one small-extent fiber core, which transports the second laser beam 15A.

Preferably, the beam switch 17 includes a combination of several discrete beam switches and/or beam switches for gradual or stepwise distribution of the first laser beam 13A, such that the same can be coupled into some or all of the fiber cores having a larger cross-section, in particular with a predetermined energy distribution. Thus, when evenly coupling the first laser beam 13A′ into the large-diameter fiber cores, a beam profile similar to that of the transport fiber 41 is achieved. By differently distributing energy to the large-diameter fiber cores in a discrete, gradual or stepwise manner, also unevenly distributed beam profiles can be achieved, which, for example, allow for an irradiation of the powder bed where the powder is pre-heated or post-heated to a varying extent.

FIG. 2 further illustrates the concept of, e.g., simultaneous, use of laser beams having different beam qualities in the manufacturing process of the workpiece 11.

FIG. 2 illustrates a core area 25A, generated solely by energy input of the first laser beam 13A. However, the energy input by the fist laser beam 13A may be reduced to an extent that, over the large focus area of the first laser beam 13A, re-melting of the powder 7 no longer takes place in the interaction zone 45. By additional and, in particular, simultaneous irradiation of the second laser beam 15A, an additional energy input can be provided in a small area of the focus zone of the second laser beam 15A. That energy input allows for formation of a fine structure in the, e.g., skin, portion 27.

Consequently, applying the disclosed concept of providing a plurality of beams having different beam qualities may allow for forming, for example, skin and core areas quickly and efficiently, due to the flexibility of the energy input by, for example, two beams having different beam qualities.

FIG. 2 further shows an additional beam source 47, which either provides laser light of low beam quality in addition to the first beam source 13, or which can be used as a single, first beam source for the laser beam 13A, which has a low beam quality. In the latter case, the first laser beam 13A and the second laser beam 15A originate from separate beam sources. By comparison, the previously described use of a pump laser of the second beam source 15 as the first beam source 13 requires a less complex irradiation system 3.

FIG. 3 shows a flow diagram for illustrating different methods for adjusting a spatially adapted irradiation in additive manufacturing of workpieces by a laser-based additive manufacturing device as, for example, shown in FIGS. 1 and 2.

Starting point of the additive manufacturing is a planning phase 51. In this phase, geometry and structure of the workpiece to be produced are defined. In a subsequent configuration phase 53, the manufacturing device is adjusted in accordance with the required irradiation, e.g., energy inputs, beam position, scanning speed, among other parameters. The configuration phase 53 includes, on the one hand, steps carried out prior to the start of production and, on the other hand, steps that can be continuously carried out during the manufacturing process. The manufacturing of the workpiece is performed in a manufacturing phase 55, where a scanning process 55A is carried out with appropriately adjusted irradiation parameters like, for example, set energy inputs and positions.

The planning phase 51 includes, for example, defining the geometry of the workpiece, in particular defining of areas of geometry like skin areas and core areas. Further, the scanning process is defined in the planning phase 51, in particular by defining, for example, the scanning speed, the focal size, and the respective types of beams to be taken as a basis (definition step 51A), and the corresponding energy inputs are assigned to the types of beams (assigning step 51B). The planning phase 51 may include further steps, for example, process-favorable arrangement of a plurality of workpieces for simultaneously manufacturing the same in a common manufacturing phase 55.

The configuration phase 53 includes, for example, provision of a first laser beam and a second laser beam (providing step 53A). Here, the second laser beam for fine irradiation of the powder bed has a beam quality higher than that of the first laser beam. The configuration phase 53 further includes setting the energy inputs of the first laser beam and the second laser beam into a superimposed beam path (energy input setting step 53B). Further, the configuration phase may include coupling out part of a pump laser beam before entering the laser resonator (out-coupling setting step 53C). Generally, the configuration phase 53 may include alternating or simultaneous coupling of laser beams into a super-positioned beam path of the scanner optics. Further, in the configuration phase 53, the step of providing 53A may include coupling the first laser beam and/or the second laser beam into a transport fiber.

In a monitoring step 57, the manufacturing phase 55 can be monitored, thus allowing for gaining additional information and contributing the same to the configuration phase 53.

In some embodiments, a direct diode laser, or a direct diode laser in combination with a fiber laser is/are used. The respective laser beams are coupled into the scanner optics by a fast beam switch, in order to successively or simultaneously irradiate different areas of geometry with different laser beams. Usually, an already effected geometric segmentation into different sub-areas (skin/core/transition areas) can be carried out in order to allocate these areas to the respective laser. Thus, in a manufacturing device, laser beams having a high beam quality can be used for different filigree structures and contour regions, and laser beams having a noticeably lower beam quality, but a higher electrical-optical efficiency, can be used for an area irradiation.

As described above, controlling of two lasers may be performed by a process control, where the geometry information on the different sub-areas (skin/core and filigree/area irradiation) is provided separately and correspondingly allocated to the lasers. In this control, control of the beam switch and, thus, control of the beam path is performed in order to switch the respectively required laser to a scanner optics. The laser output is, for example coupled into the scanner by collimation, in order to be then projected onto the powder bed/a workpiece to be produced, by an optics.

Generally, the beam guiding system may include beam forming and beam guiding elements like mirrors and lenses. Further components of additive manufacturing devices include, for ex-ample, powder providing components and gas supply systems etc.

Robust production machines for additive series production of metal or ceramic components may be applied in the field of medicine and dental technology (e.g., for producing precisely fitting implants), aviation industry (e.g., for producing turbine blades), and automotive industry (e.g., for producing engine mounts).

It is explicitly stated that all features disclosed in the description and/or the claims are intended to be disclosed separately and independently from each other for the purpose of original disclosure as well as for the purpose of restricting the claimed invention independent of the composition of the features in the embodiments and/or the claims. It is explicitly stated that all value ranges or indications of groups of entities disclose every possible intermediate value or intermediate entity for the purpose of original disclosure as well as for the purpose of restricting the claimed invention, in particular as limits of value ranges.

A number of embodiments have been described. Nevertheless, it will be understood that various modifications may be made without departing from the spirit and scope of the invention. Accordingly, other embodiments are within the scope of the following claims.

### List of Reference Numerals

1. additive manufacturing device
3 irradiation system
5 manufacturing space
7 powder
9 powder bed
11 workpiece
13 first beam source
13A′ first laser beam
13B′ pump beam path
15 second laser beam source
15A second laser beam
15A′ second beam path
17 beam switch
19 beam combiner
21 scanner optics
21′ superimposed beam path
23 scanning path
25 (core) section
25A core area
27 (skin) section
27A skin area
29 monitoring device
31 control device
31A control connections
33 diode laser units
33A diode laser unit
33A′ beam path
41 transport fiber
43 beam combiner
45 interaction zone
47 additional first beam source
51 planning phase
51A definition step
51B allocation step
53 configuration phase
53A provision step
53B energy input setting step
53C coupling out setting step
55 manufacturing phase
55A scanning process
57 monitoring step

What is claimed is:

1. An irradiation system for a device for laser-based additive manufacturing, the system comprising:
a first beam source configured to output a first laser beam and a second beam source configured to output a second laser beam, wherein the second laser beam has a beam quality higher than a beam quality of the first laser beam,
a common scanner optics arranged to focus the first laser beam and the second laser beam within a manufacturing space of the device, and
a beam guiding system comprising a first beam path along which the first laser beam is guided from the first beam source to the scanner optics during operation of the irradiation system, and a second beam path along which the second laser beam is guided from the second beam source to the scanner optics during operation of the irradiation system, wherein the beam guiding system further comprises a beam combiner arranged to superimpose the first beam path and the second beam path, wherein
the first beam source is a pump laser, the second beam source is a laser resonator pumped by the pump laser, and the beam guiding system further comprises a beam switch arranged between the pump laser and the laser resonator and adapted to feed the first laser beam into a pump laser beam path , which extends between the beam switch and the laser resonator, and/or into the first beam path.

2. An irradiation system for a device for laser-based additive manufacturing, the system comprising:
a first beam source configured to output a first laser beam, and a second beam source configured to output a second laser beam, wherein the second laser beam has a beam quality higher than a beam quality of the first laser beam;
a common scanner optics arranged to focus the first laser beam and the second laser beam within a manufacturing space of the device; and
a beam guiding system comprising a first beam path along which the first laser beam is guided from the first beam source to the scanner optics during operation of the system, and a second beam path along which the second laser beam is guided from the second beam source to the scanner optics during operation of the system, wherein the beam guiding system further comprises a beam combiner arranged to superimpose the first beam path and the second beam path, wherein
the beam guiding system further comprising a transport fiber having a central area for guiding a beam having a high beam quality, and a cladding area surrounding the central area, for guiding a beam having a low beam quality, wherein the first laser beam is couplable into the central area of the transport fiber and the second laser beam is couplable into the cladding area surrounding the central area such that, when the laser light exits the transport fiber, a beam portion originating from the first laser beam has a beam quality lower than that of a beam portion originating from the second laser beam, and/or
wherein the beam guiding system further comprises a fiber bundle structure, including at least one fiber core for guiding a beam having a high beam quality, and additional fiber cores for guiding a beam having a low beam quality, wherein the first laser beam is couplable into the at least one fiber core, and the second laser beam is couplable into the additional fiber cores by the beam combiner such that, when the laser light exits the transport fiber, a beam portion originating from the first laser beam has a beam quality lower than that of a beam portion originating from the second laser beam.

3. The irradiation system according to claim 1, wherein
the beam guiding system further comprising a transport fiber having a central area for guiding a beam having a high beam quality, and a cladding area surrounding the central area for guiding a beam having a low beam quality, wherein, the first laser beam is couplable into the central area of the transport fiber, and the second laser beam is couplable into the cladding area surrounding the central area such that, when the laser light exits the transport fiber, a beam portion originating from the first laser beam has a beam quality lower than that of a beam portion originating from the second laser beam, and/or
wherein the beam guiding system further comprises a fiber bundle structure including at least one fiber core for guiding a beam having a high beam quality, and additional fiber cores for guiding a beam having a low beam quality, wherein, the first laser beam is couplable into the at least one fiber core, and the second laser beam is couplable into the additional fiber cores by the beam combiner such that, when the laser light exits the transport fiber, a beam portion originating from the first laser beam has a beam quality lower than that of a beam portion originating from the second laser beam.

4. The irradiation system according to claim 1, wherein the beam combiner is optically arranged between the first beam source and the scanner optics, as well as between the second beam source and the scanner optics, and wherein the beam combiner is arranged to superimpose the first beam path and the second beam path into a common beam path of the scanner optics, and wherein the beam combiner is arranged upstream of the transport fiber.

5. The irradiation system according to claim 1, further comprising:
a monitoring device to monitor an energy input by the first laser beam and/or an energy input by the second laser beam, the monitoring device being configured to monitor a temperature distribution in a powder bed of the device.

6. The irradiation system according to claim 1, further comprising:
a control device configured to adjust an output of the first beam source, and
wherein the first beam source comprises a plurality of diode laser units.

7. The irradiation system according to claim 1, wherein the first beam source comprises a diode laser, and the second beam source comprises a fiber laser or a disk laser.

8. The irradiation system according to claim 1, wherein the beam switch comprises a switchable deflection mirror for the first laser beam.

9. A manufacturing device for additive manufacturing of a workpiece, the manufacturing device comprising:
a manufacturing space;
a powder bed arranged in the manufacturing space; and
an irradiation system according to claim 1 for focusing laser radiation in the powder bed.

10. A method for setting a spatially adapted irradiation for additive manufacturing of a workpiece in a laser-based additive manufacturing device comprising a scanner optics and a powder bed, the method comprising:
providing a first laser beam and a second laser beam, wherein the second laser beam has a beam quality higher than a beam quality of the first laser beam;
adjusting energy inputs of the first laser beam and the second laser beam in a superimposed beam path in the scanner optics; and
scanning the first laser beam and the second laser beam over the powder bed by alternatingly or simultaneously irradiating the powder bed with the first laser beam and the second laser beam,
wherein the laser-based additive manufacturing device further comprises an irradiation system including a diode pump laser, a laser resonator and a scanner optics, and wherein
providing the second laser beam comprises pumping the laser resonator with a pump laser beam of the diode pump laser, and
adjusting the energy inputs of the first laser beam and the second laser beam comprises coupling out a portion of the pump laser beam before entry into the laser resonator and/or alternatingly or simultaneously coupling the first laser beam and the second laser beam into the superimposed beam path of the scanner optics.

11. A method for setting a spatially adapted irradiation for additive manufacturing of a workpiece in a laser-based additive manufacturing device with a scanner optics and a powder bed, the method comprising:
providing a first laser beam and a second laser beam, wherein the second laser beam has a beam quality higher than a beam quality of the first laser beam;
adjusting energy inputs of the first laser beam and the second laser beam in a superimposed beam path in the scanner optics; and
scanning the first laser beam and the second laser beam over the powder bed by alternating or simultaneously irradiating the powder bed with the first laser beam and the second laser beam,
wherein providing the first laser beam and the second laser beam comprises coupling the first laser beam and the second laser beam into a transport fiber, wherein the second laser beam is coupled into a central area of the transport fiber, and a portion of a pump laser beam is coupled into a cladding area of the transport fiber such that, when light is emitted from the transport fiber, a beam portion originating from the second laser beam has a beam quality higher than a beam quality of a beam portion originating from the first laser beam .

12. The method according to claim 10, wherein
providing the first laser beam and the second laser beam comprises coupling the first laser beam and the second laser beam into a transport fiber, wherein the second laser beam is coupled into a central area of the transport fiber, and a portion of a pump laser beam is coupled into a cladding area of the transport fiber such that, when the laser light is emitted from the transport fiber, a beam portion originating from the second laser beam has a beam quality higher than a beam quality of a beam portion originating from the first laser beam.

13. The method according to claim 10, further comprising:
defining areas of geometry of the workpiece to be generated; and
adjusting the energy inputs of the first laser beam and of the second laser beam based on the type of powder, the scanning speed, and a selected area of geometry of the workpiece to be generated.

14. The method according to claim 10, further comprising:
monitoring an interaction zone with regard to the energy inputs supplied by the first laser beam and/or the second laser beam by measuring a spatial temperature distribution, and
adjusting the energies of the first laser beam and/or the second laser beam based on the monitoring.

15. The irradiation system of claim 4, wherein the beam combiner comprises, a dichroic mirror, the transport fiber, or both a dichroic mirror and the transport fiber.

16. The irradiation system of claim 5, wherein the monitoring device comprises an infrared camera.

17. The irradiation system of claim 6, wherein the control device is configured to control the switch to set a size of a portion of the first laser beam that is coupled to the first beam path, and wherein an output power of the first beam source is adjustable.

18. The method of claim 13, wherein adjusting the energy inputs comprises adjusting a pump power of a diode pump laser and/or adjusting an amount of laser power supplied from a pump laser to the first beam path.

19. The method according to claim 14, wherein adjusting the energies of the first laser beam and/or the second laser beam comprises adjusting a pump power of a diode pump laser.

20. The method according to claim 14, wherein adjusting the energies of the first laser beam and/or the second laser beam comprises adjusting an amount of laser power supplied from a pump laser to the first beam path.
